(19) United States
(12) Patent Application Publication
(10) Pub. No.: US 2023/0017218 A1
(43) Pub. Date: Jan. 19, 2023

(54) SEMICONDUCTOR DEVICE AND MANUFACTURING METHOD OF SEMICONDUCTOR DEVICE

(71) Applicant: Kioxia Corporation, Tokyo (JP)

(72) Inventors: Yasuhiro UCHIYAMA, Yokkaichi Mie (JP); Shinya ARAI, Yokkaichi Mie (JP); Koichi SAKATA, Yokkaichi Mie (JP); Takahiro TOMIMATSU, Yokkaichi Mie (JP)

(73) Assignee: Kioxia Corporation, Tokyo (JP)

(21) Appl. No.: 17/952,718

(22) Filed: Sep. 26, 2022

Related U.S. Application Data
(63) Continuation of application No. 16/510,488, filed on Jul. 12, 2019.

(30) Foreign Application Priority Data
Mar. 7, 2019 (JP) JP 2019-041867

(51) Int. Cl. H01L 29/06; H01L 21/761; H01L 21/762

(52) U.S. Cl. CPC H01L 29/0646; H01L 21/761; H01L 21/76251; H01L 21/76275

(57) ABSTRACT

A semiconductor device including a first chip and a second chip. The first chip includes: a first substrate; a first transistor that is provided on the first substrate; and a first pad that is provided above the first transistor and that is electrically connected to the first transistor. The second chip includes: a second pad that is provided on the first pad; a second substrate that is provided above the second pad and that includes a first diffusion layer and a second diffusion layer, at least one of the first diffusion layer and the second diffusion layer being electrically connected to the second pad; and an isolation insulating film or an isolation trench that extends at least from an upper surface of the second substrate to a lower surface of the second substrate within the second substrate and that isolates the first diffusion layer from the second diffusion layer.

This application claims the benefit of and priority to Japanese Patent Application No. 2019-041867, filed Mar. 7, 2019, the entire contents of which are incorporated herein by reference.

### FIELD

Embodiments described herein relate generally to a semiconductor device and a manufacturing method of the semiconductor device.

### BACKGROUND

Some comparative devices include a semiconductor device formed by joining two substrates having CMOS transistors formed thereon. In such a semiconductor device, in a case of, for example, thinning of one of the substrates, a leak current may occur between diffusion layers adjacent to a surface of the thinned substrate.

### DESCRIPTION OF THE DRAWINGS

FIG. 1 is a cross-sectional view (1/2) depicting a manufacturing method of a semiconductor device according to a first embodiment.

FIG. 2 is a cross-sectional view (2/2) depicting the manufacturing method of the semiconductor device according to the first embodiment.

FIG. 3 is a cross-sectional view depicting a structure of the semiconductor device according to the first embodiment.

FIGS. 4A and 4B are other cross-sectional views depicting the manufacturing method of the semiconductor device according to the first embodiment.

FIG. 5 is a cross-sectional view depicting a manufacturing method of a semiconductor device according to a comparative example.

FIG. 6 is a cross-sectional view (1/3) depicting a manufacturing method of a semiconductor device according to a second embodiment.

FIG. 7 is a cross-sectional view (2/3) depicting the manufacturing method of the semiconductor device according to the second embodiment.

FIG. 8 is a cross-sectional view (3/3) depicting the manufacturing method of the semiconductor device according to the second embodiment.

FIG. 9 is a cross-sectional view depicting a structure of the semiconductor device according to the second embodiment.

FIG. 10 is a cross-sectional view depicting a structure of a semiconductor device according to a third embodiment.

FIG. 11 is a cross-sectional view depicting a structure of a columnar portion in the semiconductor device according to the third embodiment.

FIG. 12 is a cross-sectional view (1/5) depicting a manufacturing method of the semiconductor device according to the third embodiment.

FIG. 13 is a cross-sectional view (2/5) depicting the manufacturing method of the semiconductor device according to the third embodiment.

FIG. 14 is a cross-sectional view (3/5) depicting the manufacturing method of the semiconductor device according to the third embodiment.

FIG. 15 is a cross-sectional view (4/5) depicting the manufacturing method of the semiconductor device according to the third embodiment.

FIG. 16 is a cross-sectional view (5/5) depicting the manufacturing method of the semiconductor device according to the third embodiment.

FIG. 17 is a cross-sectional view depicting a structure of the semiconductor device according to the third embodiment.

FIGS. 18A and 18B are cross-sectional views depicting a manufacturing method of the semiconductor device having another structure as the semiconductor device according to the third embodiment.

FIG. 19 is a cross-sectional view depicting the manufacturing method of the semiconductor device according to the third embodiment.

### DETAILED DESCRIPTION

Embodiments described herein provide for a semiconductor device and a manufacturing method of a semiconductor device capable of reducing occurrence of a leak current via a surface of a substrate of the semiconductor device.

In general, according to one embodiment, a semiconductor device including a first chip and a second chip. The first chip includes: a first substrate; a first transistor that is provided on the first substrate; and a first pad that is provided above the first transistor and that is electrically connected to the first transistor. The second chip includes: a second pad that is provided on the first pad; a second substrate that is provided above the second pad and that includes a first diffusion layer and a second diffusion layer, at least one of the first diffusion layer and the second diffusion layer being electrically connected to the second pad; and an isolation insulating film or an isolation trench that extends at least from an upper surface of the second substrate to a lower surface of the second substrate within the second substrate and that isolates the first diffusion layer from the second diffusion layer.

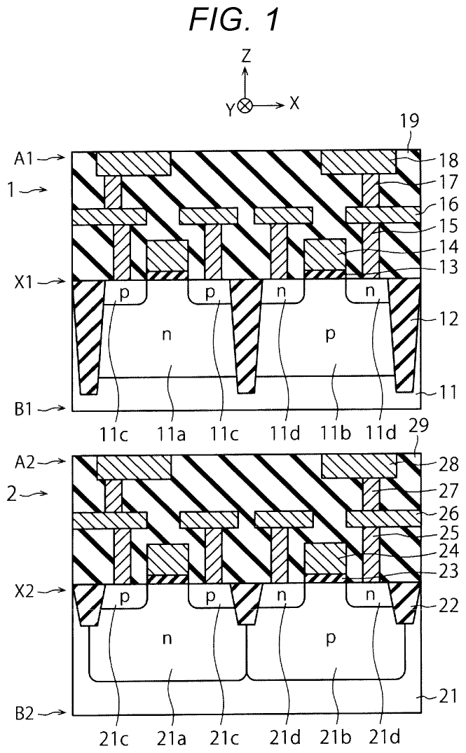

Embodiments of the present disclosure will be described hereinafter with reference to the drawings. In FIGS. 1 to 19, same or similar configurations are denoted by same reference signs and redundant description is omitted.

### First Embodiment

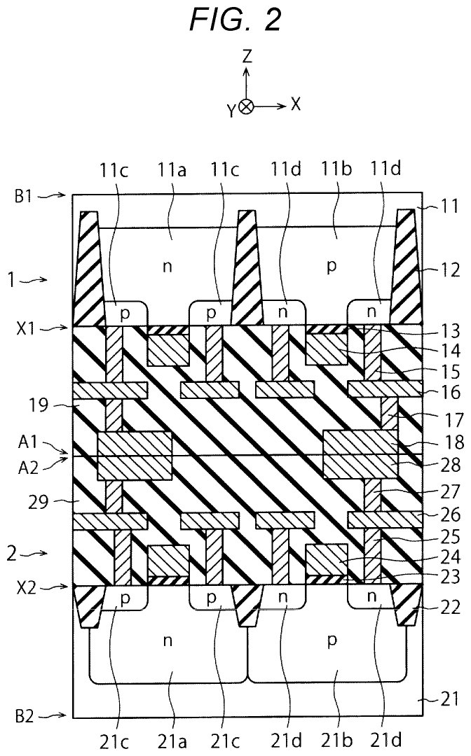

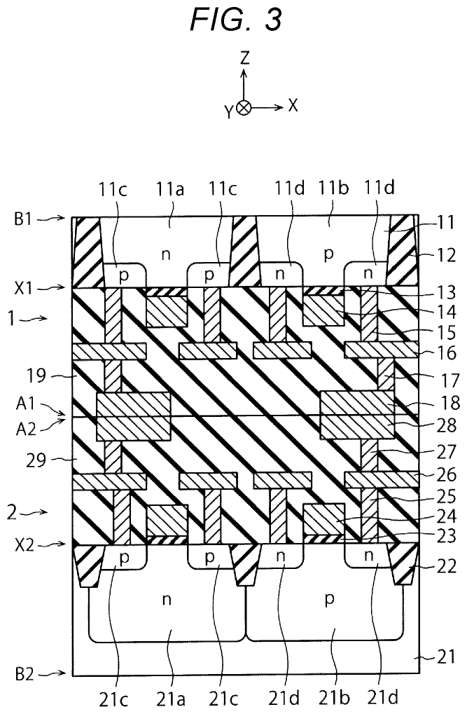

FIGS. 1 and 2 are cross-sectional views depicting a manufacturing method of a semiconductor device according to a first embodiment. FIG. 3 is a cross-sectional view depicting a structure of the semiconductor device according to the first embodiment. An example of manufacturing the semiconductor device in the present embodiment will be described below with reference to FIGS. 1 to 3, in order.

First, an upper wafer 1 and a lower wafer 2 are prepared (FIG. 1). The lower wafer 2 is an example of a first wafer and the upper wafer 1 is an example of a second wafer.

The upper wafer 1 includes a substrate 11, an element isolation insulating film 12, and a plurality of MOSFETs, and each MOSFET includes a gate insulating film 13 and a gate electrode 14. These MOSFETs are examples of a second transistor. The upper wafer 1 also includes a plurality of contact plugs 15, an interconnection layer 16 including a plurality of interconnections, a plurality of via plugs 17, a plurality of metal pads 18, and an interlayer insulating film 19. The substrate 11 is an example of a second substrate and the metal pads 18 are an example of a second pad. Furthermore, the substrate 11 includes an re-diffusion layer 11a, a p-diffusion layer 11b, a plurality of p-diffusion layers 11c, and a plurality of n-diffusion layers 11d.

The lower wafer 2 includes a substrate 21, an element isolation insulating film 22, and a plurality of MOSFETs, and each MOSFET includes a gate insulating film 23 and a gate electrode 24. These MOSFETs are examples of a first transistor. The lower wafer 2 also includes a plurality of contact plugs 25, an interconnection layer 26 including a plurality of interconnections, a plurality of via plugs 27, a plurality of metal pads 28, and an interlayer insulating film 29. The substrate 21 is an example of a first substrate and the metal pads 28 are an example of a first pad. Furthermore, the substrate 21 includes an re-diffusion layer 21a, a p-diffusion layer 21b, a plurality of p-diffusion layers 21c, and a plurality of n-diffusion layers 21d.

FIG. 1 depicts a first surface A1 and a second surface B1 of the upper wafer 1 and one principal surface X1 of the substrate 11. The second surface B1 corresponds to the other principal surface (rear surface) of the substrate 11. Moreover, FIG. 1 depicts a first surface A2 and a second surface B2 of the lower wafer 2 and one principal surface X2 of the substrate 21. The second surface B2 corresponds to the other principal surface (rear surface) of the substrate 21.

FIG. 1 depicts an X direction and a Y direction parallel to the principal surfaces X1, B1, X2, and B2 of the substrates 11 and 21 and perpendicular to each other, and a Z direction perpendicular to the principal surfaces X1, B1, X2, and B2 of the substrates 11 and 21. While a +Z direction is referred to as an upward direction and a −Z direction is referred to as a downward direction in the present specification, the −Z direction may either match or not match a gravity direction.

Examples of the substrate 11 include a semiconductor substrate such as a silicon substrate. In the present embodiment, the n-diffusion layer (n-well) 11a and the p-diffusion layer (p-well) 11b are formed first within the substrate 11 by a method such as ion implantation. Next, an element isolation trench is formed within the principal surface X1 of the substrate 11 and the element isolation insulating film 12 is formed within the element isolation trench. The element isolation insulating film 12 is, for example, a silicon oxide film and a depth of the element isolation trench is, for example, approximately 5 μm. It is to be noted that the element isolation insulating film 12 penetrates the n-diffusion layer 11a and the p-diffusion layer 11b and does not penetrate the substrate 11 in FIG. 1. The element isolation insulating film 12 is formed between the n-diffusion layer 11a and the p-diffusion layer 11b. An n type and a p type are an example of first and second conduction type, respectively.

Next, the gate insulating film 13 and the gate electrode 14 of a p-MOSFET are formed on the n-diffusion layer 11a, and the gate insulating film 13 and the gate electrode 14 of an n-MOSFET are formed on the p-diffusion layer 11b. Next, the p-diffusion layers 11c that function as source and drain regions are formed within the re-diffusion layer 11a, and the n-diffusion layers 11d that function as source and drain regions are formed within the p-diffusion layer 11b.

Next, the contact plugs 15 are formed on the p-diffusion layers 11c, the n-diffusion layers 11d, and the like, the interconnection layer 16 is formed on the contact plugs 15, the via plugs 17 are formed on the interconnection layer 16, and the metal pads 18 are formed on the via plugs 17. As a result, various interconnections are formed on the substrate 11. The metal pads 18 include, for example, copper (Cu) and electrically connected to the MOSFETs described above via the interconnection layer 16 and the like. The interlayer insulating film 19 includes a plurality of insulating films. The various interconnections and these insulating films in the interlayer insulating film 19 are alternately formed on the substrate 11.

Processes of preparing the lower wafer 2 are executed similarly to those of preparing the upper wafer 1. The substrate 21, the element isolation insulating film 22, the gate insulating film 23, the gate electrode 24, the contact plugs 25, the interconnection layer 26, the plurality of via plugs 27, the metal pads 28, and the interlayer insulating film 29 are respectively processed similarly to the substrate 11, the element isolation insulating film 12, the gate insulating film 13, the gate electrode 14, the plurality of contact plugs 15, the interconnection layer 16, the plurality of via plugs 17, the metal pads 18, and the interlayer insulating film 19, respectively. It is to be noted that the element isolation insulating film 22 does not penetrate the n-diffusion layer 21a and the p-diffusion layer 21b in FIG. 1.

Next, the upper wafer 1 and the lower wafer 2 are bonded (e.g. surfaces A1 and A2 are bonded) so that each metal pad 18 is disposed on a respective corresponding metal pad 28, and the upper wafer 1 and the lower wafer 2 are heated (FIG. 2). As a result, the metal pads 18 and 28 are fused and joined and the upper wafer 1 and the lower wafer 2 are electrically connected to each other via the metal pads 18 and 28. It is to be noted that an orientation of the upper wafer 1 of FIG. 2 is flipped compared to that of the upper wafer 1 of FIG. 1.

Next, the principal surface B1 of the substrate 11 of the upper wafer 1 is polished either mechanically or chemically to thin the substrate 11 (FIG. 3). As a result, the film thickness of the substrate 11 is made thinner and the element isolation insulating film 12 is exposed to the principal surface B1 of the substrate 11. An upper surface of the element isolation insulating film 12 and an upper surface of the substrate 11 may thus be made substantially coplanar. Thus, the element isolation insulating film 12 is formed to extend from the principal surface B1 (upper surface) to the principal surface X1 (lower surface) of the substrate 11. Furthermore, the n-diffusion layer 11a and the p-diffusion layer 11b are also exposed to the principal surface B1 by thinning the substrate 11. Thus, the re-diffusion layer 11a and the p-diffusion layer 11b are also formed to extend from the principal surface B1 (upper surface) to the principal surface X1 (lower surface) of the substrate 11. The substrate 11 in the present embodiment is thinned until a thickness thereof is equal to approximately 3 μm. According to the present embodiment, such thinning of the substrate 11 enables improvement in a degree of integration of the semiconductor device.

Subsequently, the upper wafer 1 and the lower wafer 2 are cut into a plurality of chips. Each chip eventually includes an upper chip including a portion of the upper wafer 1 and a lower chip including a portion of the lower wafer 2. FIGS. 1 to 3 depict a region including an upper chip and a lower chip. In this way, the semiconductor device in the present embodiment having the structure depicted in FIG. 3 is manufactured. The lower chip is an example of a first chip and the upper chip is an example of a second chip.

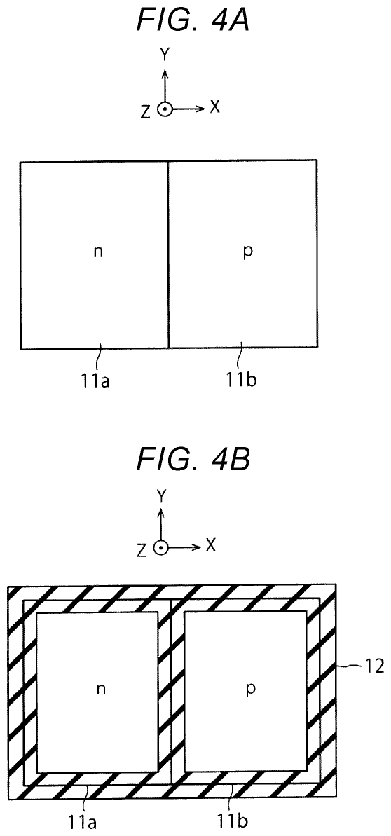

FIGS. 4A and 4B are other cross-sectional views depicting the manufacturing method related to the semiconductor device in the first embodiment.

FIG. 4A depicts the n-diffusion layer 11a and the p-diffusion layer 11b before the element isolation insulating film 12 is formed, and FIG. 4B depicts the re-diffusion layer 11a and the p-diffusion layer 11b after the element isolation insulating film 12 is formed. These cross-sectional views each depict an XY cross-section of the substrate 11.

As depicted in FIG. 4B, the element isolation insulating film 12 is formed to surround each of the re-diffusion layer 11a and the p-diffusion layer 11b. The re-diffusion layer 11a and the p-diffusion layer 11b are thereby isolated from each other. Furthermore, the re-diffusion layer 11a is isolated from other wells within the substrate 11 and the p-diffusion layer 11b is isolated from other wells within the substrate 11. The n-diffusion layer 11a and the p-diffusion layer 11b are an example of part of the substrate 11 surrounded by the element isolation insulating film 12. It is noted that FIG. 4B depicts border lines of the n-diffusion layer 11a and the p-diffusion layer 11b before formation of the element isolation insulating film 12 to make description understandable.

It is noted that planar shapes of the re-diffusion layer 21a, the p-diffusion layer 21b, and the element isolation insulating film 22 are similar to those of the n-diffusion layer 11a, the p-diffusion layer 11b, and the element isolation insulating film 12. However, since the element isolation insulating film 12 is thinner than the element isolation insulating film 22, the re-diffusion layer 21a and the p-diffusion layer 21b each include a portion surrounded by the element isolation insulating film 22 and a portion that is not surrounded by (is exposed from) the element isolation insulating film 22.

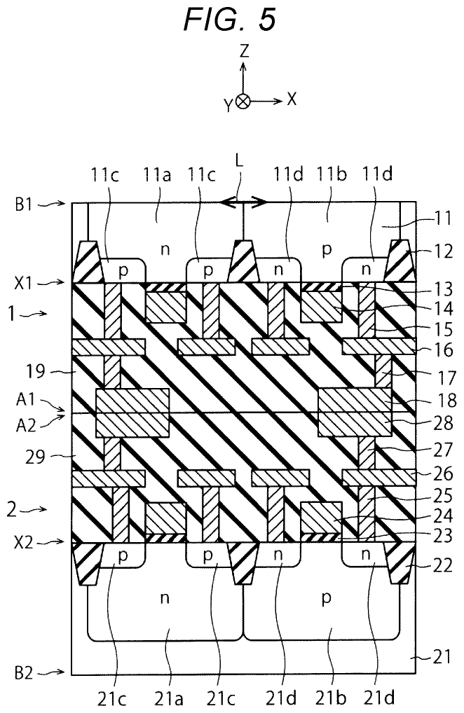

FIG. 5 is a cross-sectional view depicting a manufacturing method of a semiconductor device according to a comparative example.

While FIG. 5 corresponds to processes of FIG. 3, FIG. 5 differs from FIG. 3 in a relationship between the substrate 11 and the element isolation insulating film 12. Specifically, in FIG. 5, the n-diffusion layer 11a and the p-diffusion layer 11b are exposed to the principal surface B1 of the substrate 11, while the element isolation insulating film 12 is not exposed to the principal surface B1 of the substrate 11.

In FIG. 5, contact between a depletion layer within the substrate 11 and the principal surface B1 (polished surface, rear surface) of the substrate 11 when the completed semiconductor device operates possibly causes occurrence of a leak current as indicated by an arrow L in the principal surface B1 between the n-diffusion layer 11a and the p-diffusion layer 11b, possibly resulting in occurrence of a malfunction of the semiconductor device. This is considered to be caused by a crystal defect present in the principal surface B1 of the substrate 11. Design specifications may include making the substrate 11 thick so that the depletion layer within the substrate 11 is out of contact with the principal surface B1 of the substrate 11 to avoid this malfunction; however, making the substrate 11 thick may undesirably cause a reduction in the degree of integration of the semiconductor device.

On the other hand, the element isolation insulating film 12 is exposed to the principal surface B1 of the substrate 11 in FIG. 3. Thus, even with the contact between the depletion layer within the substrate 11 and the principal surface B1 of the substrate 11 when the completed semiconductor device operates, it is possible to reduce the occurrence of the leak current described above since the element isolation insulating film 12 is present on the principal surface B1 of the substrate 11. According to the present embodiment, therefore, it is possible to thin the substrate 11 and to improve the degree of integration of the semiconductor device while reducing the occurrence of the leak current.

As described so far, the semiconductor device in the present embodiment includes the element isolation insulating film 12 that extends from the principal surface B1 to the principal surface X1 of the substrate 11 of the upper chip. According to the present embodiment, therefore, it is possible to reduce the occurrence of the leak current via the surface of the substrate 11.

It is noted that examples of the upper chip 1 and the lower chip 2 in the present embodiment include a DRAM (Dynamic Random Access Memory) and peripheral circuits of the DRAM, and a PCM (Phase Change Memory) and peripheral circuits of the PCM. It is noted, however, that configurations of the upper chip 1 and the lower chip 2 in the present embodiment are not limited to these examples.

### Second Embodiment

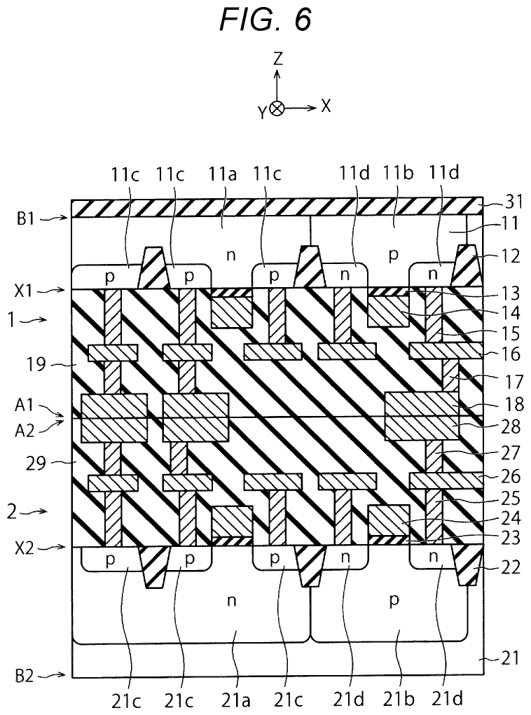

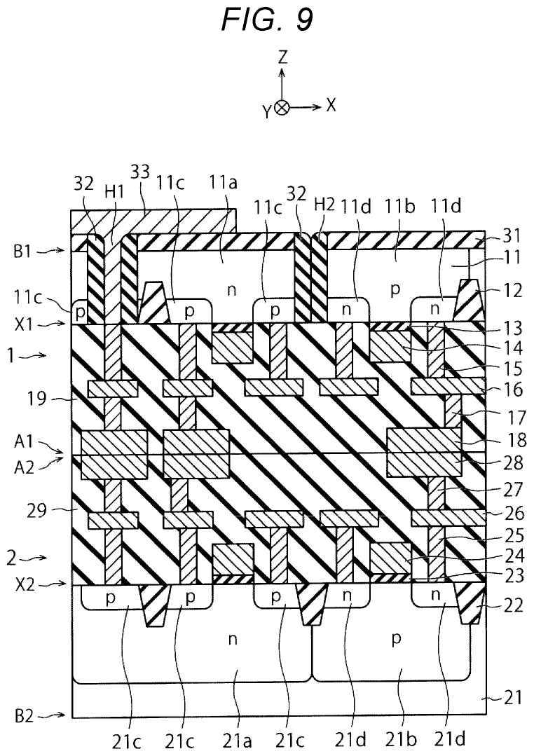

FIGS. 6 to 8 are cross-sectional views depicting a manufacturing method of a semiconductor device according to a second embodiment. FIG. 9 is a cross-sectional view depicting a structure of the semiconductor device according to the second embodiment. An example of manufacturing the semiconductor device in the present embodiment will be described below with reference to FIGS. 6 to 9 in order.

First, after executing processes in FIGS. 1 to 3, an upper insulating film 31 is formed on the substrate 11 of the upper wafer 1 (FIG. 6). It is to be noted, however, that a thickness of the element isolation insulating film 12 in the present embodiment is smaller than that of the element isolation insulating film 12 in the first embodiment. The element isolation insulating film 12 in the present embodiment is, therefore, not exposed to the principal surface B1 of the substrate 11. Examples of the upper insulating film 31 include a silicon oxide film. The upper insulating film 31 is an example of a second insulating film.

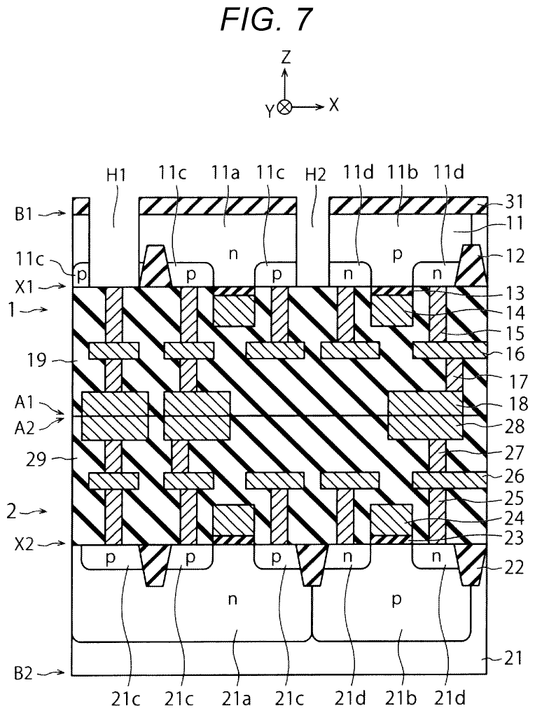

Next, a hole H1 and an element isolation trench H2 penetrating the upper insulating film 31 and the substrate 11 are formed by, for example, lithography and dry etching (FIG. 7). The hole H1 is formed on the contact plug 15. The element isolation trench H2 is formed between the n-diffusion layer 11a and the p-diffusion layer 11b. Furthermore, the element isolation trench H2 is formed to surround each of the n-diffusion layer 11a and the p-diffusion layer 11b similarly to the element isolation insulating film 12 of FIG. 4B.

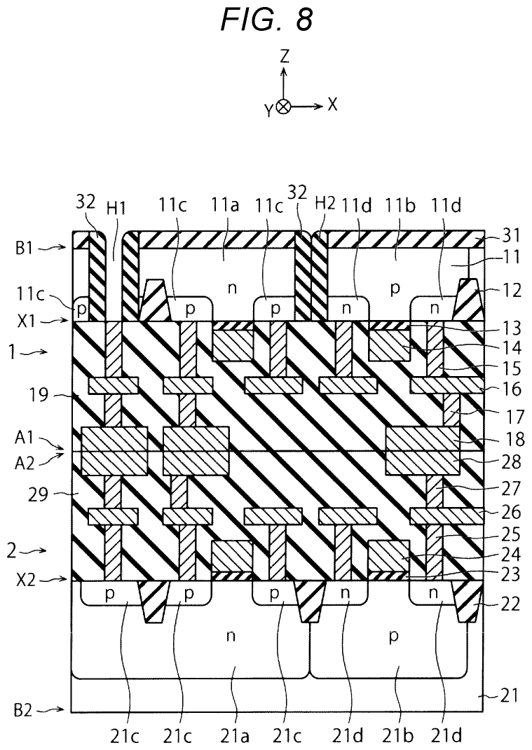

Next, side wall insulating films 32 are formed on side surfaces of the substrate 11 and the upper insulating film 31 within the hole H1 and the element isolation trench H2 (FIG. 8). It is to be noted that the element isolation trench H2 is substantially closed by the side wall insulating films 32 and the hole H1 is not closed by the side wall insulating films 32 (a substantial portion (e.g. a central portion) of the hole H1 remains unfilled by the side wall insulating films 32 (e.g. such that the contact plug 15 remains substantially exposed from the side wall insulating films 32). Examples of the side wall insulating film 32 include a silicon oxide film. The side wall insulating films 32 within the element isolation trench H2 function as an element isolation insulating film. In the present embodiment, the insulating films (side wall insulating films 32) include the same material as that of the element isolation insulating film. The side wall insulating films 32 within the hole H1 are an example of a first insulating film. FIG. 8 depicts a seam remaining on upper surfaces or the like of the side wall insulating films 32 within the element isolation trench H2. The seam can constitute at least a portion of an indentation in the upper surface of the side wall insulating film 32 within the element isolation trench H2. Thus, at least a portion of the upper surface of the side wall insulating film 32 is provided at a position lower than a position of the upper surface of upper insulating film 31.

Next, an interconnection layer 33 is deposited on the upper insulating film 31, the side wall insulating films 32, and the like and the interconnection layer 33 is patterned (FIG. 9). As a result, the interconnection layer 33 is formed within the holes H1 and on the upper insulating film 31. Examples of the interconnection layer 33 include an Al (aluminum) layer and a Cu (copper) layer. A portion of the interconnection layer 33 within the hole H1 functions as a plug, while a portion of the interconnection layer 33 on the upper insulating film 31 functions as a metal pad on this plug. This metal pad is an example of a third pad and is used, for example, as an external connection pad for wire bonding. On the other hand, the plug is formed to extend from an upper surface of the upper insulating film 31 to the lower surface (principal surface X1) of the substrate 11, and formed on the side surfaces of the upper insulating film 31 and the substrate 11 via the side wall insulating films 32. Furthermore, the plug is electrically connected to not only the interconnection layer 16 within the upper wafer 1 but also the interconnection layer 26 within the lower wafer 2 via the metal pads 18 and 28.

Subsequently, the upper wafer 1 and the lower wafer 2 are cut into a plurality of chips. Each chip eventually includes the upper chip including a portion of the upper wafer 1 and the lower chip including a portion of the lower wafer 2. FIGS. 6 to 9 depict a region including the upper chip and the lower chip. In this way, the semiconductor device in the present embodiment having the structure depicted in FIG. 9 is manufactured.

The element isolation insulating film 12 in the first embodiment is formed before the upper wafer 1 and the lower wafer 2 are bonded, while the element isolation insulating film (side wall insulating films 32) within the element isolation trench H2 in the present embodiment is formed after the upper wafer 1 and the lower wafer 2 are bonded. According to the present embodiment, similarly to the first embodiment, it is possible to reduce the occurrence of the leak current via the surface of the substrate 11 using such an element isolation insulating film.

In the present embodiment, an insulating film other than the side wall insulating films 32 may be deposited in the element isolation trench H2. It is noted, however, that in a case of depositing the side wall insulating films 32 within the element isolation trench H2, the element isolation insulating film can be formed simultaneously with the side wall insulating films 32 formed within the hole H1 as a foundation layer of the plug and that the element isolation insulating film can be formed simply. Furthermore, in the present embodiment, the insulating film may not be deposited within the element isolation trench H2 and the element isolation trench H2 with an air gap may remain in the completed semiconductor device. Moreover, while processes in FIGS. 7 and 8 are carried out after the upper wafer 1 and the lower wafer 2 are bonded in the present embodiment, the processes therein may be carried out before the upper wafer 1 and the lower wafer 2 are bonded.

### Third Embodiment

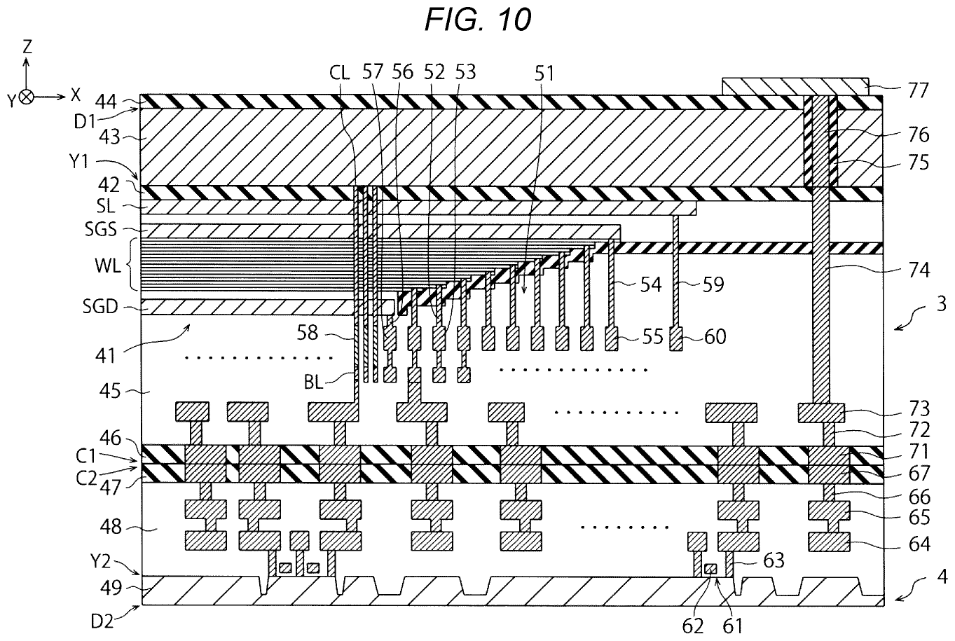

FIG. 10 is a cross-sectional view depicting a structure of a semiconductor device according to a third embodiment. The semiconductor device of FIG. 10 is a three-dimensional memory formed by bonding an array chip 3 and a circuit chip 4.

The array chip 3 includes a memory cell array 41 including a plurality of memory cells (cell transistors), an insulating layer 42 on the memory cell array 41, a substrate 43 on the insulating layer 42, an insulating layer 44 on the substrate 43, an interlayer insulating film 45 under the memory cell array 41, and an upper insulating layer 46 under the interlayer insulating film 45. Examples of the insulating layers 42 and 44 include a silicon oxide film and a silicon nitride film. Examples of the substrate include a semiconductor substrate such as a silicon substrate. FIG. 10 depicts a first surface C1 and a second surface D2 of the array chip 3 and one principal surface Y1 of the substrate 43. The second surface D1 corresponds to the other principal surface (rear surface) of the substrate 43. The array chip 3 is an example of the second chip and the substrate 43 is an example of the second substrate.

It is noted that the insulating layer 44, an insulating film 75, a second plug 76, and a metal pad 77 are formed after the array chip 3 and the circuit chip 4 are bonded, as described later. Owing to this, the second surface D1 of the array chip 3 is specified here for a stage of manufacture of the array chip 3 that does not include the insulating layer 44 and the like for the sake of convenience.

The circuit chip 4 is provided under the array chip 3. The circuit chip 4 includes a lower insulating layer 47, an interlayer insulating film 48 under the lower insulating layer 47, and a substrate 49 under the interlayer insulating film 48. Examples of the substrate 49 include a semiconductor substrate such as a silicon substrate. FIG. 10 depicts a first surface C2 and a second surface D2 of the circuit chip 4 and one principal surface Y2 of the substrate 49. The second surface D2 corresponds to the other principal surface (rear surface) of the substrate 49. The circuit chip 4 is an example of the first chip and the substrate 49 is an example of the first substrate.

The array chip 3 includes, as electrode layers within the memory cell array 41, a plurality of word lines WL, a source-side selection gate SGS, a drain-side selection gate SGD, and a source line SL. FIG. 10 depicts a stair structure portion 51 of the memory cell array 41. As depicted in FIG. 10, each word line WL is electrically connected to a word interconnection layer 53 via a contact plug 52, and the source-side selection gate SGS is electrically connected to a source-side selection gate interconnection layer 55 via a connection plug 54. Furthermore, the drain-side selection gate SGD is electrically connected to a drain-side selection gate interconnection layer 57 via a contact plug 56, and the source line SL is electrically connected to a source interconnection layer 60 via a contact plug 59. A columnar portion CL that penetrates the word lines WL, the source-side selection gate SGS, the drain-side selection gate SGD, and the source line SL is electrically connected to a bit line BL via a plug 58 and is also electrically connected to the substrate 43.

The circuit chip 4 includes a plurality of transistors 61. Each transistor 61 includes a gate electrode 62 provided on the substrate 49 via a gate insulating film, and a source diffusion layer and a drain diffusion layer, not depicted, provided within the substrate 49. The circuit chip 4 also includes a plurality of plugs 63 provided on either the source diffusion layers or the drain diffusion layers of these transistors 61, an interconnection layer 64 provided on these plugs 63 and including a plurality of interconnections, and an interconnection layer 65 provided on the interconnection layer 64 and including a plurality of interconnections. Furthermore, the circuit chip 4 includes a plurality of via plugs 66 provided on the interconnection layer 65, and a plurality of lower metal pads 67 provided on these via plugs 66 within the lower insulating layer 47. The lower metal pads 67 are an example of the first pad.

The array chip 3 includes a plurality of upper metal pads 71 provided on the lower metal pads 67 within the upper insulating layer 46, a plurality of via plugs 72 provided on the upper metal pads 71, and an interconnection layer 73 provided on these via plugs 72 and including a plurality of interconnections. Each word line WL or each bit line BL in the present embodiment is electrically connected to the corresponding interconnection within the interconnection layer 73. The upper metal pads 71 are an example of the second pad. Moreover, the array chip 3 includes a first plug 74 provided within the interlayer insulating film 45 and the insulating layer 42 and provided on the interconnection layer 73, a second plug 76 provided within the substrate 43 and the insulating layer 44 via the insulating film 75 and provided on the first plug 74, and the metal pad 77 provided on the insulating layer 44 and provided on the second plug 76. The metal pad 77 is an external connection pad of the semiconductor device in the present embodiment, and can be connected to a mounting substrate or the other device via a solder ball, a metal bump, a bonding wire, or the like. The insulating film 75, the insulating layer 44, and the metal pad 77 are an example of the first insulating film, the second insulating film, and the third pad, respectively.

While the lower insulating layer 46 is formed on a lower surface of the interlayer insulating film 45 in the present embodiment, the lower insulating layer 46 may be provided in and integrated with the interlayer insulating film 45 (e.g. such that the interlayer insulating film 45 and the lower insulating layer 46 constitute a monolithic structure). Likewise, while the upper insulating layer 47 is formed on an upper surface of the interlayer insulating film 48 in the present embodiment, the upper insulating layer 47 may be provided in and integrated with the interlayer insulating film 48 (e.g. such that the interlayer insulating film 48 and the upper insulating layer 47 constitute a monolithic structure).

FIG. 11 is a cross-sectional view depicting a structure of the columnar portion CL in the semiconductor device according to the third embodiment.

As depicted in FIG. 11, the memory cell array 41 includes the plurality of word lines WL and a plurality of insulating layers 81 alternately stacked on the interlayer insulating film 45. Examples of each word line WL include a tungsten (W) layer. Examples of each insulating layer 81 include a silicon oxide film.

The columnar portion CL includes a block insulating film 82, a charge storage layer 83, a tunnel insulating film 84, a channel semiconductor layer 85, and a core insulating film 86 in order. The charge storage layer 83 is, for example, a silicon nitride film and formed on side surfaces of the word lines WL and the insulating layers via the block insulating film 82. The channel semiconductor layer 85 is, for example, a silicon layer and formed on a side surface of the charge storage layer 83 via the tunnel insulating film 84. Examples of the block insulating film 82, the tunnel insulating film 84, and the core insulating film 86 include a silicon oxide film and a metal insulating film.

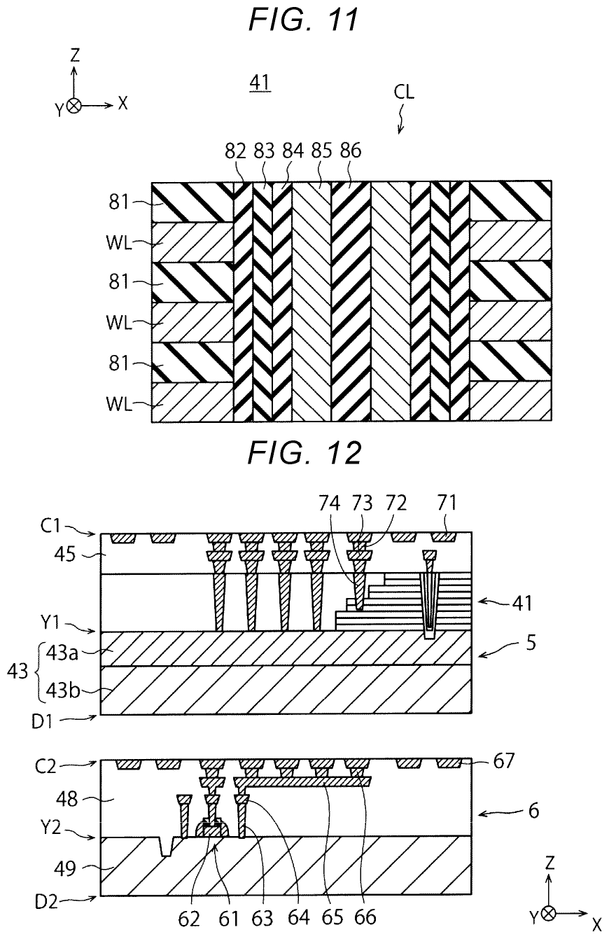

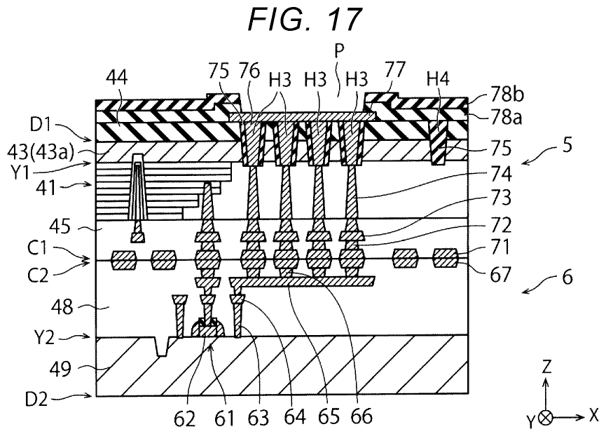

FIGS. 12 to 16 are cross-sectional views depicting a manufacturing method of the semiconductor device according to the third embodiment. FIG. 17 is a cross-sectional view depicting a structure of the semiconductor device according to the third embodiment. In FIGS. 12 to 17, certain components (or portions thereof) depicted in FIG. 10 are omitted for the sake of convenience of description. An example of manufacturing the semiconductor device in the present embodiment will be described with reference to FIGS. 12 to 17, in that order.

FIG. 12 depicts an array wafer 5 including one or more array chips 3 and a circuit wafer 6 including one or more circuit chips 4. The array wafer 5 is also referred to as “memory wafer”, while the circuit wafer 6 is also referred to as “CMOS wafer”. It is to be noted that an orientation of the array wafer 5 of FIG. 12 is flipped compared to that of the array chip 3 of FIG. 10. In FIG. 12, the array wafer 5 already includes the first plug 74 and does not include the insulating film 75, the second plug 76, and the metal pad 77 yet. Furthermore, the substrate 43 includes a well (diffusion layer) 43a and a remaining portion 43b.

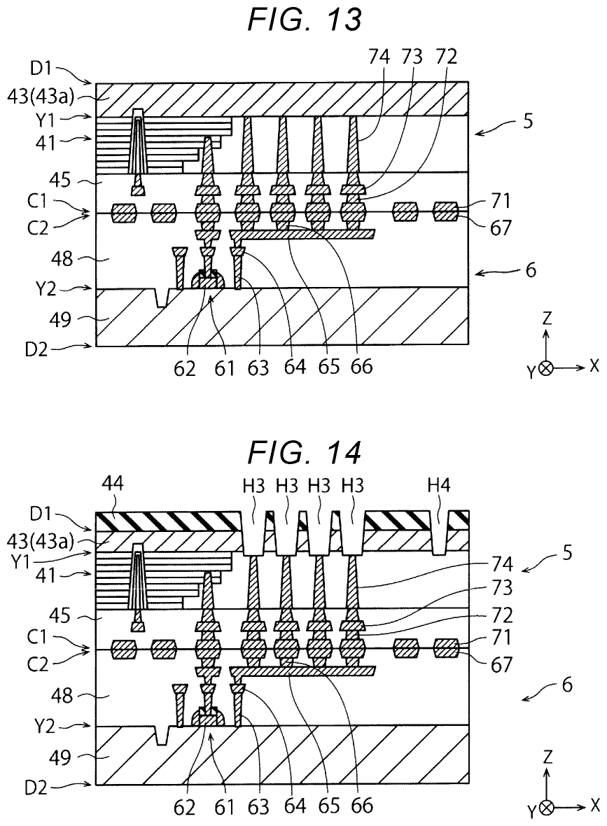

First, the array wafer 5 and the circuit wafer 6 are bonded by a mechanical pressure (FIG. 13). The upper insulating layer 46 and the lower insulating layer 47 (refer to FIG. 10) are thereby adhesively bonded. Next, the array wafer 5 and the circuit wafer 6 are annealed at approximately 400° C. (FIG. 13). The upper metal pads 71 and the lower metal pads 67 are thereby joined. Next, the remaining portion 43b other than the well 43a is removed from the substrate 43 by thinning the substrate 43 (FIG. 13). The substrate 43 is thinned by, for example, CMP (Chemical Mechanical Polishing).

Next, the insulating layer 44 is formed on the substrate 43 and holes H3 and an element isolation trench H4 that penetrate the insulating layer 44 and the substrate 43 are formed by RIE (Reactive Ion Etching) (FIG. 14). As a result, the first plug 74 is exposed in each hole H3. FIG. 14 depicts four first plugs 74 exposed in four holes H3, respectively. Examples of the insulating layer 44 include a silicon oxide film. The insulating layer 44 is an example of the second insulating film.

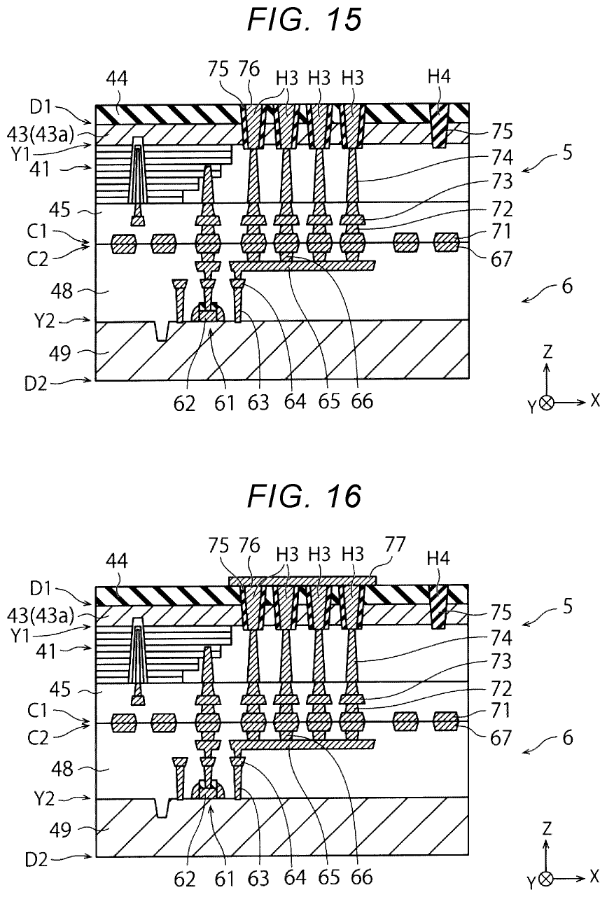

Next, the insulating film 75 is formed on side surfaces of the substrate 43 and the insulating layer 44 within the holes H3 and the element isolation trench H4 (FIG. 15). It is to be noted that the element isolation trench H4 is substantially closed by the insulating film 75 and the holes H3 are not fully closed by the insulating film 75. Examples of the insulating film 75 include a silicon oxide film. The insulating film 75 within the element isolation trench H4 functions as an element isolation insulating film. In the present embodiment, the insulating film (insulating film 75) includes the same material as that of this element isolation insulating film is formed in each hole H3. The insulating film 75 within the hole H3 is an example of the first insulating film.

Next, a second plug 76 is formed within each hole H3 via the insulating film 75 (FIG. 15). As a result, four second plugs 76 are formed on the four first plugs 74. The second plugs 76 are formed by, for example, an Al (aluminum) layer or a Cu (copper) layer. The second plugs are formed to extend from an upper surface of the insulating film 75 to the lower surface (principal surface Y1) of the substrate 43. Furthermore, the first plugs 75 and the second plugs 76 are electrically connected to not only the interconnection layer 73 within the array wafer 5 but also the interconnection layers 64 and 65 within the circuit wafer 6 via the lower metal pads 67 and the upper metal pads 71.

Next, the metal pad 77 is formed on the second plugs (FIG. 16). The metal pad 77 is formed by, for example, an Al layer or a Cu layer. FIG. 16 depicts one metal pad 77 formed on the four second plugs 76. The metal pad 77 is an example of the third pad and is used, for example, as an external connection pad for wire bonding. While the second plugs 76 and the metal pad 77 are formed by the different interconnection layers in the present embodiment, the second plugs 76 and the metal pad 77 may be formed by the same interconnection layer (e.g. and the second plugs 76 and the metal pad 77 may constitute a monolithic structure).

Next, a passivation film 78 that includes a lower film 78a and an upper portion 78b is formed on an entire surface of the substrate 43 (FIG. 17). Next, an opening P that penetrates the passivation film 78 is formed by RIE (FIG. 17). As a result, the metal pad 77 is exposed in the opening P.

Subsequently, the substrate 43 is thinned by CMP, and the array wafer 5 and the circuit wafer 6 are diced into a plurality of chips. Each chip eventually includes the array chip 3 including a portion of the array wafer 5 and the circuit chip 4 including a portion of the circuit wafer 6. In this way, the semiconductor device in the present embodiment having the structure depicted in FIG. 17 is manufactured.

In the present embodiment, an insulating film other than the insulating film 75 may be deposited in the element isolation trench H4. It is noted, however, that in a case of depositing the insulating film 75 within the element isolation trench H4, the element isolation insulating film can be formed simultaneously with the insulating film 75 formed within each hole H1 as a foundation layer of each second plug 75 and that the element isolation insulating film can be formed simply. Furthermore, in the present embodiment, the insulating films may not be deposited within the element isolation trench H4 and the element isolation trench H4 with an air gap may remain in the completed semiconductor device. Moreover, while processes in FIGS. 14 and 15 are carried out after the array wafer 5 and the circuit wafer 6 are bonded in the present embodiment, the processes therein may be carried out before the array wafer 5 and the circuit wafer 6 are bonded.

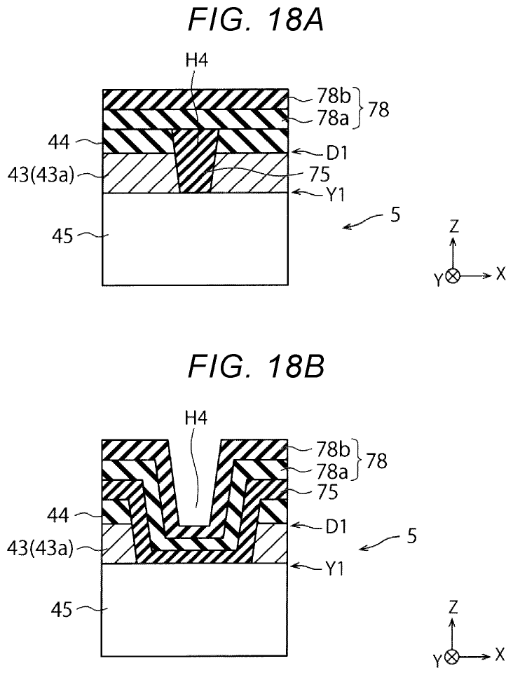

FIGS. 18A and 18B are cross-sectional views depicting a manufacturing method of the semiconductor device having another structure as the semiconductor device according to the third embodiment.

FIG. 18A depicts a first example of the insulating film 75 deposited in the element isolation trench H4. In the present example, the element isolation trench H4 is substantially closed by the insulating film 75 similarly to a case of FIG. 17. This can be achieved by setting a thickness of the insulating film 75 to be equal to or larger than half of an opening width of the element isolation trench H4.

FIG. 18B depicts a second example of the insulating film 75 deposited in the element isolation trench H4. In the present example, the element isolation trench H4 is not closed by the insulating film 75. This can be achieved by setting the thickness of the insulating film 75 to be smaller than half of the opening width of the element isolation trench H4.

The insulating film 75 of FIG. 18B has an upper surface within the element isolation trench H4, an upper surface outside of the element isolation trench H4, and side surfaces (inclined surfaces) between these upper surfaces. The upper surface of the insulating film 75 within the element isolation trench H4 is set at a position lower than that of an upper surface of the insulating layer 44. Specifically, the upper surface is provided at a height between the principal surface D1 (upper surface) and the principal surface Y1 (lower surface) of the substrate 43. Furthermore, part of the passivation film 78 enters into the element isolation trench H4.

The insulating film 75 within the element isolation trench H4 in the present embodiment may be formed in a shape according to any of the first and second examples shown in FIGS. 18A and 18B.

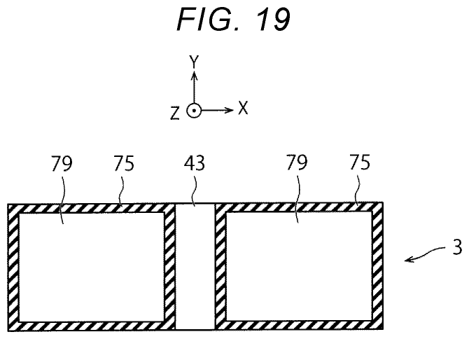

FIG. 19 is a cross-sectional view depicting the manufacturing method of the semiconductor device according to the third embodiment.

The memory cell array 41 in the present embodiment includes the plurality of memory cells and these memory cells operate per a unit referred to as a “plane”. Specifically, a write operation, a read operation, and an erase operation on the memory cells are performed per plane.

FIG. 19 is a schematic cross-sectional view depicting an XY cross-section of the substrate 43, and depicts two unit regions 79 within the substrate 43 and two insulating films 75 formed within the substrate 43 and functioning as element isolation insulating films. Each of these insulating films is formed to surround one unit region 79.

Each unit region 79 in the present embodiment corresponds to one plane. One plane is, therefore, provided near the principal surface Y1 of each unit region 79. The element isolation insulating films (insulating films 75) in the present embodiment, therefore, isolate the unit regions 79 from each other and, as a result of isolation of the unit regions 79, isolate the planes from each other. Each unit region 79 is an example of part of the substrate 43 surrounded by the element isolation insulating film.

As described so far, the semiconductor device in the present embodiment includes the element isolation insulating film (insulating film 75) that extends from the principal surface D1 to the principal surface Y1 of the substrate 43 of the array chip 3. According to the present embodiment, therefore, similarly to the first and second embodiments, it is possible to reduce the occurrence of the leak current via the surface of the substrate 43.

While the array wafer 5 and the circuit wafer 6 are bonded in the present embodiment, the array wafers 5 may be bonded as an alternative to bonding between the array wafer 5 and the circuit wafer 6. Features described above with reference to FIGS. 10 to 19 are also applicable to the bonding between the array wafers 5.

Furthermore, while FIG. 10 depicts a boundary surface between the upper insulating layer 46 and the lower insulating layer 47 and boundary surfaces between the upper metal pads 71 and the lower metal pads 67, these boundary surfaces are normally unobservable after annealing described above. Nevertheless, positions at which these boundary surfaces were present can be estimated by, for example, detecting inclinations of side surfaces of the upper metal pads 71 and those of the lower metal pads 67 or position gaps between the side surfaces of the upper metal pads 71 and those of the lower metal pads 67.

As used herein, the terms “approximately” and “substantially” are used to describe and account for small variations. When used in conjunction with an event or circumstance, the terms “approximately” and “substantially” can refer to instances in which the event or circumstance occurs precisely as well as instances in which the event or circumstance occurs to a close approximation. For example, when used in conjunction with a numerical value, the terms “approximately” and “substantially” can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

While certain embodiments have been described, these embodiments have been presented by way of example only, and are not intended to limit the scope of the present disclosure. Indeed, the embodiments described herein may be embodied in a variety of other forms; furthermore, various omissions, substitutions and changes in the form of the embodiments described herein may be made without departing from the spirit of the present disclosure. The different embodiments or features described herein, or portions thereof, may be combined. The accompanying claims and their equivalents are intended to cover such forms or modifications as would fall within the scope and spirit of the present disclosure.

1-20. (canceled)

21. A semiconductor device comprising:
a first chip including:
a first substrate; and
a first transistor that is provided on the first substrate; and
a second chip bonded to the first chip and including:
a memory cell array including a plurality of electrode layers stacked in a first direction and a columnar portion including a semiconductor layer and penetrating the plurality of electrode layers in the first direction;
a second substrate that is provided above the memory cell array and includes a first diffusion layer and a second diffusion layer, the first diffusion layer being electrically connected to the semiconductor layer;
an isolation insulating film or an isolation trench that extends at least from an upper surface of the second substrate to a lower surface of the second substrate within the second substrate but does not extend beyond a bonding surface between the first chip and the second chip, and that isolates the first diffusion layer from the second diffusion layer; and
at least one bonding metal provided on the bonding surface and electrically connecting the first transistor to the memory cell array, wherein
the isolation insulating film or the isolation trench has an upper portion having a first width in a second direction and a lower portion having a second width in the second direction,
the second direction is parallel to the upper surface of the second substrate, and
the first width is greater than the second width.

22. The semiconductor device according to claim 21, wherein
the isolation insulating film or the isolation trench surrounds at least a portion of the second substrate.

23. The semiconductor device according to claim 21, wherein
the second chip further includes:
a plug that extends from the upper surface of the second substrate to the lower surface of the second substrate within the second substrate, and
a third pad that is provided on the plug.

24. The semiconductor device according to claim 23, wherein
the second chip includes the isolation insulating film, and
the plug is provided within the second substrate and is surrounded by a first insulating film including a same material as a material of the isolation insulating film.

25. The semiconductor device according to claim 24, wherein the first insulating film and the isolation insulating film constitute a monolithic structure.

26. The semiconductor device according to claim 24, wherein
the plug is electrically connected to an interconnect layer within the first chip via a first pad and second pad.

27. The semiconductor device according to claim 21, wherein
the isolation insulating film or the isolation trench is provided between the first diffusion layer and the second diffusion layer.

28. The semiconductor device according to claim 27, wherein
the first diffusion layer and the second diffusion layer extend from the upper surface of the second substrate to the lower surface of the second substrate within the second substrate.

29. The semiconductor device according to claim 28, wherein
the isolation insulating film or the isolation trench surrounds at least one of the first and second diffusion layers.

30. The semiconductor device according to claim 21, wherein
the second chip further includes a second insulating film that is provided on the second substrate, and
the isolation insulating film or the isolation trench extends from an upper surface of the second insulating film provided on the second substrate to the lower surface of the second substrate within the second substrate and the second insulating film.

31. The semiconductor device according to claim 30, wherein
the second chip comprises the isolation insulating film, and
at least a portion of an upper surface of the isolation insulating film is provided at a position lower than a position of the upper surface of the second insulating film.

32. A manufacturing method of a semiconductor device, comprising:
forming a first transistor on a first wafer;
forming a first pad that is electrically connected to the first transistor of the first wafer above the first transistor;
forming a first diffusion layer and a second diffusion layer within a second wafer;
forming an isolation insulating film or an isolation trench that extends at least from an upper surface of the second wafer to a lower surface of the second wafer within the second wafer and that isolates the first diffusion layer from the second diffusion layer;
forming a second pad that is electrically connected to at least one of the first diffusion layer and the second diffusion layer above the second wafer;
bonding the first wafer and the second wafer so that the second pad is disposed on the first pad; and
forming a chip by dicing the bonded wafers.

33. The manufacturing method of the semiconductor device according to claim 32, comprising
bonding the first wafer and the second wafer after forming the isolation insulating film or the isolation trench within the second wafer.

34. The manufacturing method of the semiconductor device according to claim 32, comprising
forming the isolation insulating film or the isolation trench within the second wafer after bonding the first wafer and the second wafer.

35. The manufacturing method of the semiconductor device according to claim 32, comprising:
forming the isolation insulating film that extends at least from the upper surface of the second wafer to the lower surface of the second wafer within the second wafer, wherein forming the isolation insulating film comprises polishing an upper surface of the substrate of the second wafer to expose an upper surface of the isolation insulating film from the substrate.

36. The manufacturing method of the semiconductor device according to claim 35, wherein polishing the substrate is performed such that the upper surface of the isolation insulating film is coplanar with the upper surface of the substrate of the second wafer.
